(19) United States
(12) Patent Application Publication
(10) Pub. No.: US 2010/0112795 A1
(43) Pub. Date: May 6, 2010

(54) METHOD OF FORMING ULTRA-SHALLOW JUNCTIONS FOR SEMICONDUCTOR DEVICES

(75) Inventors: Robert KAIM, Brookline, MA (US); Jose I. ARNO, Brookfield, CT (US); James A. DIETZ, Scarsdale, NY (US)

Correspondence Address: INTELLECTUAL PROPERTY / TECHNOLOGY LAW, PO BOX 14329, RESEARCH TRIANGLE PARK, NC, 27709, US

(73) Assignee: ADVANCED TECHNOLOGY MATERIALS, INC., Danbury, CT (US)

(21) Appl. No.: 12/570,995

(22) Filed: Sep. 30, 2009

Related U.S. Application Data
(63) Continuation-in-part of application No. PCT/US2008/058150, filed on Mar. 25, 2008.
Application No. PCT/US2008/058150 is a continuation-in-part of application No. 12/065,503, filed on Jun. 14, 2008.
(60) Provisional application No. 60/921,191, filed on Mar. 30, 2007.
(60) Provisional application No. 60/712,647, filed on Aug. 30, 2005.

(51) Int. Cl. H01L 21/265

(52) U.S. Cl. 438/515; 438/527; 118/728; 257/E21.334

(57) ABSTRACT

A first method for producing a doped region in a semiconductor substrate includes performing a first implant step in which a carborane cluster molecule is implanted into a semiconductor substrate to form a doped region. A second method for producing a semiconductor device having a shallow junction region includes providing a first gas and a second gas in a container. The first gas includes a first dopant and the second gas includes a second dopant. The second method also includes implanting the first and second dopants into a semiconductor substrate using an ion. The ion source is not turned off between the steps of implanting the first dopant and implanting the second dopant.

### CROSS REFERENCE TO RELATED APPLICATIONS

This is a continuation-in-part of International application No. PCT/US2008/058150, filed Mar. 25, 2008, which claims benefit from U.S. provisional application Ser. No. 60/921,191, filed Mar. 30, 2007. This application is also a continuation-in-part of U.S. patent application Ser. No. 12/065,503, filed Feb. 29, 2008, which is a national phase application, under 35 U.S.C. §371, based on International application No. PCT/US2006/033899, filed Aug. 30, 2006, which claims benefit from U.S. provisional application Ser. No. 60/712,647, filed Aug. 30, 2005. The disclosures of all of International Patent Application PCT/US2008/058150, U.S. Provisional Application 60/921,191, U.S. patent application Ser. No. 12/065,503, International Patent Application PCT/US2006/033899 and U.S. Provisional Application 60/712,647 are hereby incorporated herein by reference in their respective entireties, for all purposes.

### BACKGROUND

The present invention relates generally to the field of semiconductor devices such as integrated circuits, and more particularly to the formation of ultra-shallow junctions for such semiconductor devices.

In PMOS-type semiconductor devices, semiconductor substrates are doped or implanted with boron ions to form ultra-shallow junctions (e.g., source or drain junctions for integrated circuit transistors, etc.). In conventional boron doping processes, the boron ions are first implanted at relatively low implantation energies, after which the ions are electrically activated by thermal annealing to form the junction.

One issue associated with the use of boron ions in forming such junctions is that the ions may diffuse into undesirable locations in the semiconductor substrate during subsequent annealing steps, which may be detrimental to the performance of the semiconductor device. Crystalline defects created during implantation of the boron ions may be at least partially responsible for this diffusion phenomenon.

One method for reducing the magnitude of undesirable boron diffusion involves the implantation of fluorine ions prior to the thermal annealing step. The implanted fluorine ions may advantageously act to stabilize the silicon lattice damage created during boron ion implantation, which in turn may reduce the boron ion diffusion upon annealing and allow for the formation of shallower junctions in the substrate. It has further been suggested that the diffusion of boron can be even further reduced by separately implanting both carbon and fluorine ions into the semiconductor substrate.

While the implantation of fluorine and/or carbon ions may allow formation of shallower junctions, the use of multiple implantation species may adversely affect the efficiency of the manufacturing process. For example, while conventional junction formation requires only a single implantation step (e.g., of boron ions), processes in which other species are implanted require additional separate implantation steps. In the case where boron, carbon, and fluorine are to be implanted in a substrate, three separate implantations may be required. Between implants, the magnets and other components of the implanter must be re-tuned to account for the different masses of the species being implanted. Additionally, with present ion source technology, each implantation may require a different source feed material, which means that between implants, a relatively time-consuming sequence must be followed in which the source is shut down, the prior feed material is pumped out, the new feed material is introduced, and the source is re-started.

### SUMMARY

An exemplary embodiment of the invention relates to a method for producing a doped region in a semiconductor substrate that includes performing a first implant step in which a carborane cluster molecule is implanted into a semiconductor substrate to form a doped region.

Another exemplary embodiment of the invention relates to an apparatus for forming doped regions in a semiconductor substrate that includes a stage for holding a semiconductor substrate and means for implanting a carborane cluster molecule into the semiconductor substrate to form a doped region.

Another exemplary embodiment of the invention relates to a method for producing a semiconductor device having a shallow junction region that includes providing a first gas and a second gas in a container. The first gas includes a first dopant and the second gas includes a second dopant. The method also includes implanting the first and second dopants into a semiconductor substrate using an ion. The ion source is not turned off between the steps of implanting the first dopant and implanting the second dopant.

### BRIEF DESCRIPTION OF THE DRAWINGS

FIG. 1 is a schematic diagram illustrating components of a system for producing semiconductor devices according to an exemplary embodiment.

FIG. 2 is a flow diagram illustrating steps in a method of forming a shallow junction in a semiconductor substrate according to an exemplary embodiment.

FIG. 3 is a cross-sectional view of a portion of a semiconductor substrate according to an exemplary embodiment.

FIG. 4 is a cross-sectional view of the portion of a semiconductor substrate shown in FIG. 3 illustrating a first dopant implantation step.

FIG. 5 is a cross-sectional view of the portion of a semiconductor substrate shown in FIG. 4 illustrating a second dopant implantation step.

FIG. 6 is a cross-sectional view of the portion of a semiconductor substrate shown in FIG. 5 illustrating a third dopant implantation step.

FIG. 7 is a flow diagram illustrating steps in a method of forming a shallow junction in a semiconductor substrate according to another exemplary embodiment.

FIG. 8 is a cross-sectional view of a portion of a semiconductor substrate according to an exemplary embodiment.

FIG. 9 is a cross-sectional view of the portion of a semiconductor substrate shown in FIG. 8 illustrating a dopant implantation step.

FIGS. 10-12 illustrate various components of an ion source configured to deliver intact cluster molecules into a semiconductor substrate.

### DETAILED DESCRIPTION

According to an exemplary embodiment, a shallow doped region is formed in a semiconductor substrate (e.g., to produce an shallow junction for a semiconductor device) by co-implanting a plurality of dopant species into the semiconductor substrate. According to a first exemplary embodiment, multiple source gases are first mixed in a container that is coupled to an ion implanter, after which each of the dopants are implanted in succession without the need to purge the ion source (according to other exemplary embodiments, the ion source may be purged between one or more of the implanting steps). According to a second exemplary embodiment, each of the dopant species are included in a single molecule which is implanted directly into a semiconductor substrate. In this latter embodiment, the implantation parameters are selected such that the various species are implanted at the proper depth and location.

The exemplary embodiments described below provide an advantageous method for forming ultra-shallow junctions for semiconductor devices that is more efficient and less labor-intensive than conventional methods. According to a particular exemplary embodiment, a method for forming such ultra-shallow junctions allows the implantation process to proceed without the need to shut down the implantation equipment and purge the ion source of previously-implanted source gas (according to other exemplary embodiments, the ion source may be purged between one or more of the implanting steps as may be desired). According to another particular exemplary embodiment, a method is provided in which multiple species are implanted simultaneously into a semiconductor substrate. It would be desirable to provide a method that utilizes any one or more of these or other advantageous features as will be apparent to those reviewing the present disclosure.

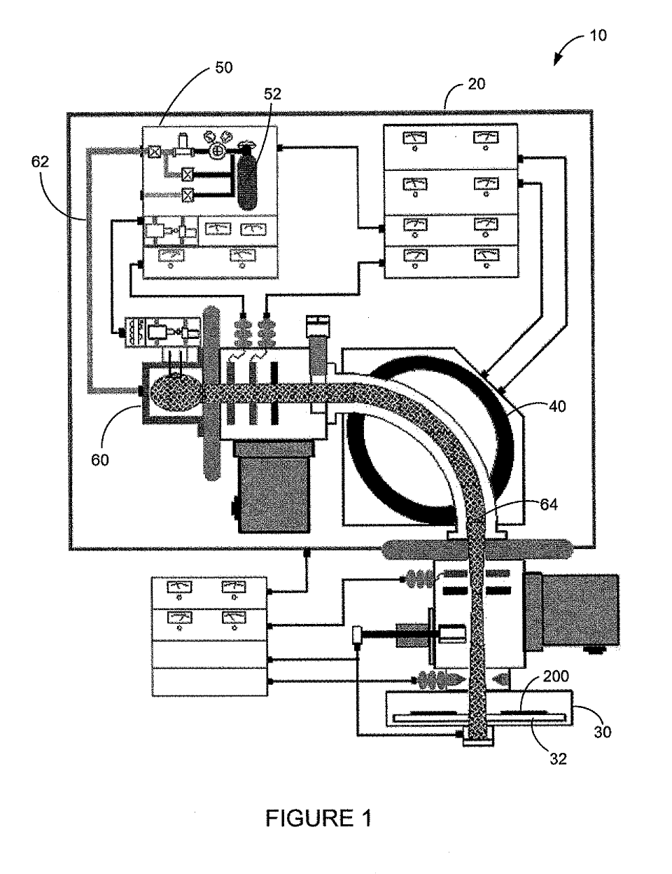

FIG. 1 is a schematic diagram illustrating a system 10 for producing semiconductor devices according to an exemplary embodiment. The system 10 includes, among other features, an implanter 20 having an ion source 60, a gas box 50 for dispensing source gases to the ion source 60 and a magnet 40 for directing an ion beam 64 at one or more semiconductor substrates or wafers 200. The substrates 200 are provided on a platform 32 (e.g., a support, stage, susceptor, etc.) or other structure within a chamber 30 during processing.

The ion implanter may be any suitable ion implanter now known or hereafter developed for use in semiconductor fabrication facilities. Examples of such implanters are available from Varian Semiconductor Equipment Associates of Gloucester, Mass.; from Axcelis Technologies of Beverly, Mass.; and Applied Materials Inc. of Santa Clara, Calif.

Within the gas box 50 is a container 52 (e.g., a vessel, gas tank, cylinder, etc.) that is configured to store and deliver high pressure gases or other fluids to the ion source 60 via a delivery line 62. For example, according to an exemplary embodiment, the container 52 is a conventional high pressure gas cylinder, with an elongate main body portion having a neck of reduced cross-sectional area relative to the main body cross-section of the vessel. The container 52 may include a valve head assembly including a valve (manual or automatic) and associated pressure and flow control elements (e.g., in a manifold arrangement). The container 52 may also include a pressure regulator and/or other features to facilitate the storage and delivery of source gases to the ion source 60.

According to an exemplary embodiment, the container 52 is a fluid storage and dispensing apparatus such as a vacuum actuated cylinder (VAC) similar to those described in U.S. Pat. No. 6,101,816; U.S. Pat. No. 6,343,476; and U.S. Pat. No. 6,089,027, the entire disclosures of which are incorporated by reference herein. According to an exemplary embodiment, the fluid storage and delivery apparatus may be a system such as that described in U.S. Pat. No. 5,518,528 (a sub-atmospheric pressure active gas storage and dispensing vessel) and commercially available from ATMI, Inc., Danbury, Conn., USA) under the trademark SDS, wherein active gas is sorptively retained on a physical adsorbent and selectively desorbed therefrom for dispensing of active gas from the vessel. In another embodiment, a neat active fluid source comprises a gas storage and dispensing vessel of the type described in U.S. Pat. No. 6,089,027 to Luping Wang, et al. and commercially available from ATMI, Inc. (Danbury, Conn.) under the trademark VAC, featuring an interiorly disposed regulator element for dispensing of the active gas at a pressure determined by the regulator set point. Other fluid storage and delivery systems may also be used, including, but not necessarily limited to, systems such as those described in U.S. Pat. No. 5,704,965; U.S. Pat. No. 6,743,278; and U.S. Pat. No. 7,172,646. According to other exemplary embodiments, the device 52 may have any design or configuration suitable for the storage and delivery of the source gases or materials described herein (e.g., it may be a gas storage and dispensing vessel or container holding the neat active gas to be diluted for use).

The fluid storage and delivery system may alternatively be constituted and/or arranged, in any suitable manner, e.g., as a supply structure, material or operation. For example, the active fluid source may include a solid physical adsorbent-based package of the type described in U.S. Pat. No. 5,518,528. In other embodiments, the active fluid may be liberated from a liquid solution, or be generated by an in-situ generator, or be generated from a reactive liquid as described in U.S. Patent Publication No. 2004/0206241 published October, 2004 for “Reactive Liquid Based Gas Storage and Delivery System,” or be obtained from a reactive solid, or from a vaporizable or sublimable solid. In general, any appropriate source or supply of the active fluid can be used. In a specific embodiment, the active fluid source includes a retention structure, as described in U.S. Pat. No. 5,916,245 issued Jun. 29, 1999 for “High Capacity Gas Storage and Dispensing System.”

Liquid precursors and/or solid precursors dissolved in suitable solvents enable the direct injection and/or liquid delivery of precursors into a CVD, ALD or RVD vaporizer unit. The accurate and precise delivery rate can be obtained through volumetric metering to achieve reproducibility during CVD, ALD or RVD metallization of a VLSI device. Solid precursor delivery via specially-designed devices, such as ATMI's ProE Vap (ATMI, Danbury, Conn., USA) enables highly efficient transport of solid precursors to a CVD or ALD reactor.

Depending on the form, e.g., solid or liquid form, of the precursor, preferred precursor storage and dispensing packages include those described in U.S. Provisional Patent Application No. 60/662,515 [WO 2006/101767] filed in the names of Paul J. Marganski, et al. for “SYSTEM FOR DELIVERY OF REAGENTS FROM SOLID SOURCES THEREOF” and the storage and dispensing apparatus variously described in U.S. Pat. No. 5,518,528; U.S. Pat. No. 5,704,965; U.S. Pat. No. 5,704,967; U.S. Pat. No. 5,707,424; U.S. Pat. No. 6,101,816; U.S. Pat. No. 6,089,027; U.S. Patent Application Publication 2004/0206241; U.S. Pat. No. 6,921,062; U.S. patent application Ser. No. 10/858,509 [Publication No. 2005/0006799]; and U.S. patent application Ser. No. 10/022,298, the disclosures of all of which are hereby incorporated herein by reference, in their respective entireties.

The ion source is fed with a source gas that include the elements to be implanted into a semiconductor substrate. The ion source forms a plasma that includes ions generated from the constituents of the source gas (e.g., B⁺, F⁻) using applied electrical energy. The ions are then accelerated toward a target (e.g., a semiconductor substrate) included in the chamber 30. The depth of penetration into the substrate is determined by a number of factors, including the energy of the ions, the type of ion species, and the composition of the substrate.

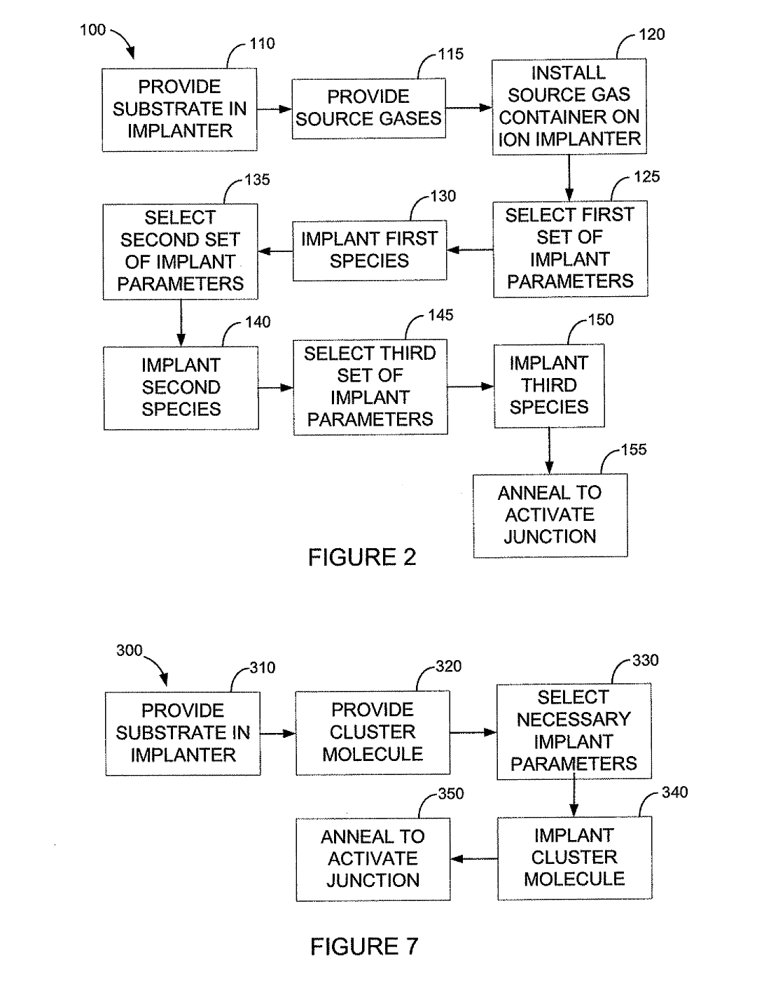

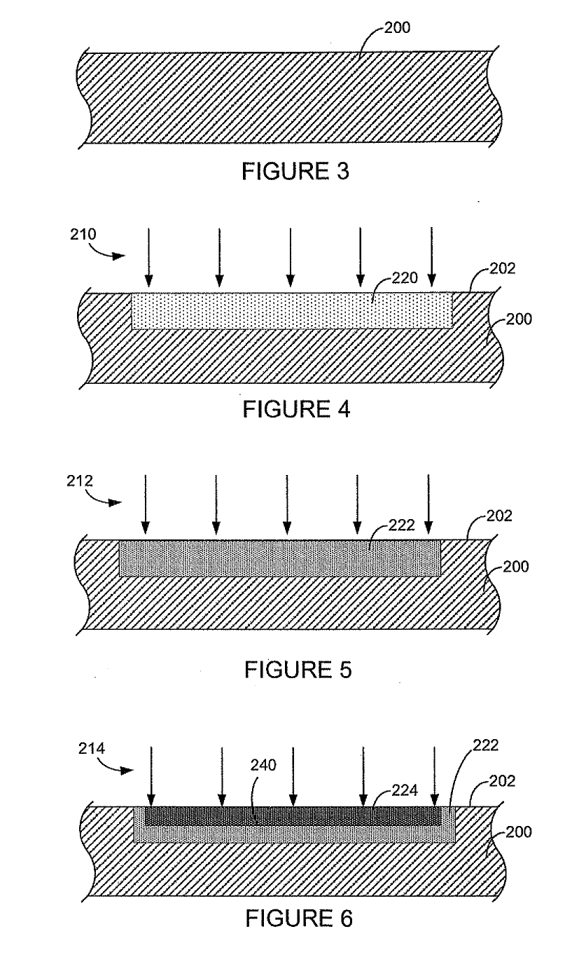

FIG. 2 is a flow diagram illustrating steps in a method 100 of forming a shallow junction in a semiconductor substrate according to an exemplary embodiment. FIGS. 3-6 are cross-sectional views of a portion of a semiconductor substrate illustrating various dopant implantation steps.

According to a step 110, a semiconductor substrate or wafer 200 (illustrated, e.g., in FIG. 3) is provided into a chamber 30 of an ion implanter (e.g., ion implanter 20 shown in FIG. 1). The substrate 200 may be provided in the form of a silicon wafer according to an exemplary embodiment. According to other exemplary embodiments, the substrate may comprise other suitable semiconducting materials such as silicon-germanium (Si—Ge) or gallium arsenide (GaAs). Additionally, the substrate may include other layers and/or materials, including buried oxide (BOX) layers and the like. The ion source may also be adapted to allow multiple substrates (e.g., wafers) to be provided within the chamber according to other exemplary embodiments.

In a step 115 of the method 100, source gases are introduced into a suitable container (e.g., the container 52 as shown in FIG. 1). According to an exemplary embodiment, the source gases are provided directly into the container. According to another exemplary embodiment, two or more dopant precursors may be flowed into a mixing chamber and optionally monitored for concentration before being fed into the ion source with a blending/metering system such as those described in U.S. Pat. No. 6,909,973; U.S. Pat. No. 7,058,519; U.S. Pat. No. 7,063,097; and U.S. Pat. No. 6,772,781.

The source gases may be selected based on the desired implantations to be made. For example, according to a particular exemplary embodiment in which boron, carbon, and fluorine ions are to be implanted into a substrate, BF₃ and CH₄ gases may be introduced into the container 52 (with the BF₃ gas providing the boron and fluorine atoms and the CH₄ gas providing the carbon atoms), with the partial pressure of BF₃ to CH₄ between approximately 10:1 and 1:4. Other suitable ratios may also be used according to other exemplary embodiments depending on the desired implantation characteristics.

Any suitable combination of gases may be used according to various exemplary embodiments. According to another particular exemplary embodiment in which boron, carbon, and fluorine ions are to be implanted into a substrate, fluorocarbon (e.g., CₓF_{y} where 1≦x≦6 and 4≦y≦14) and boron-containing gases such as boron trichloride (BCl₃) may be mixed in the container. Other potential source gases that may be used to provide the boron dopant species include boranes (e.g., BₓH_{y} where 2≦x≦18 and 6≦y≦22) and their derivatives; borohydrofluorides (e.g., BₓH_{y}F_{z} where 1≦x≦18, 1≦y≦22, and 1≦z≦26); borocarbohydrofluorides (e.g., B_{w}CₓH_{y}F_{z} where 1≦w≦18, 0≦x≦12, 0≦y≦36, and 0≦z≦14) and their derivatives; boron fluorides and their derivatives; B₂F₄; (BF₂)₃BR where R is selected from PH₃, CF₃, and CO. Large boron hydride clusters may also be used according to other exemplary embodiments having a formula BₓH_{y} where 5≦x≦96 and y≦x+8 as described, for example, in U.S. patent application Ser. No. 11/041,558 (Publication No. 2005/0163693), the disclosure of which is incorporated herein by reference.

Other potential source gases that may be used to provide the carbon and/or fluorine dopant species include hydrocarbons (e.g., CₓH_{y} where 1≦x≦10 and 4≦y≦30) and their derivatives, fluorohydrocarbons (e.g., CₓH_{y}F_{z} where 1≦x≦5, 1≦y≦20, and 1≦z≦20) and their derivatives, interhalogen species (e.g., R_{y}F_{z}, where R is chlorine, bromine, or iodine and 1≦x≦4 and 1≦y≦10), and NF₃. It should also be understood that source gases other than those described herein may be used to provide other dopant species (e.g., arsenic, phosphorous, indium, and antimony) according to other exemplary embodiments. The particular dopants and source gases may be selected based on any of a variety of factors, including the chemical stability of the gas mixture in the container and its affect on ion source performance and lifetime.

Any suitable number of source gases may be used according to various exemplary embodiments. For example, more than two different source gases may be provided in the container (e.g., a carbon source gas, a fluorine source gas, and a boron or other dopant source gas may be included in the same container). According to other embodiments, all dopants may be provided in a single source gas (e.g., (BF₂)₃BCF₃).

In a step 120, the container 52 is installed into the gas box 50 of the ion implanter 30. According to an exemplary embodiment, the container 52 may include features (e.g., threaded connectors, etc.) that are configured to couple the container 52 to the delivery line 62 and to provide a fluid tight connection between the container 52 and the delivery line 62.

According to an exemplary embodiment, each of the dopants are implanted in the substrate separately in succession. Because all source gases are already included in the same container 52, there is no need to shut down the ion source, purge the container, and restart the ion source between implant steps. Instead, ions from the source plasma are accelerated and enter a magnetic spectrometer which is tuned to a particular magnetic field which selects ions according to their mass and charge; only those ions for which the spectrometer is selective (e.g., C⁺ ions) will be directed to the substrate. Once the first implant is complete, the spectrometer will be retuned to a different field strength such that it is selective to a second type of ions included in the plasma, and so on.

In a step 125, the first set of implantation parameters are selected for the first species to be implanted into the substrate. The magnets and other components of the ion implanter may also be re-tuned as may be appropriate to select for the desired mass and energy of the dopant being implanted (e.g., the accelerating voltage and magnetic field of the implanter may be adjusted). The particular implantation parameters selected may vary according to a number of factors, including the desired concentration and implant depth in the substrate, the species being implanted, the source gas being used, and other factors. According to an exemplary embodiment in which carbon is the first species to be implanted and a CH₄ source gas is included in the container 52, the implantation energy may be selected to have a value between approximately 1 and 50 keV to obtain a concentration in the substrate of between approximately 10¹⁴ and 10¹⁵ ions/cm² at a depth of between approximately 10 and 500 nanometers.

In a step 130 shown in FIG. 4, the first dopant is implanted through a top surface 202 of the substrate 200 (as indicated by arrows 210) to a desired implantation depth and concentration. A region or area 220 is formed in the substrate 200 that includes the desired dopant (e.g., carbon dopants) within the semiconductor microstructure. According to an exemplary embodiment, the first dopant is implanted to a depth greater than the depth of the ultra-shallow junction to be produced. According to other exemplary embodiments, the first dopant may be implanted to a depth less than or equal to the depth of the ultra-shallow junction to be produced.

In a step 135, the implantation parameters are selected for the second species to be implanted into the substrate. The magnets and other components of the ion implanter may also be re-tuned as may be appropriate to select for the desired mass and energy of the dopant being implanted (e.g., the accelerating voltage and magnetic field of the implanter may be adjusted). Notably, the ion source and the delivery line 62 are not purged between implantation steps. As described above, the particular implantation parameters selected may vary according to a number of factors. According to an exemplary embodiment in which fluorine is the second species to be implanted and a BF₃ source gas is included in the container 52, the implantation energy may be selected to have a value between approximately 1 and 50 keV to obtain a concentration in the substrate of between approximately 10¹⁴ and 10¹⁵ ions/cm² at a depth of between approximately 10 and 500 nanometers.

In a step 140 shown in FIG. 5, the second dopant is implanted through a top surface 202 of the substrate 200 (as indicated by arrows 212) to a desired implantation depth and concentration. A region or area 222 is formed in the substrate 200 that includes the desired dopant (e.g., fluorine dopants) within the semiconductor microstructure. According to an exemplary embodiment, the second dopant is implanted to a depth equal to the depth of the first dopant, although according to other exemplary embodiments, the depth of the second implant may be greater or less than that of the first implant.

It should also be noted that while carbon and fluorine have been described as being implanted sequentially as the first and second dopants, respectively, according to other exemplary embodiments, the order may be reversed. Additionally, where other species are to be implanted in place of or in addition to carbon and/or fluorine, similar steps would be performed to accomplish such implantation (e.g., the parameters selected for the implantation may vary depending on the species to be implanted).

In a step 145, the implantation parameters are selected for boron ions to be implanted into the substrate. The magnets and other components of the ion implanter may also be re-tuned as may be appropriate to select for the mass and energy of the dopant being implanted (e.g., the accelerating voltage and magnetic field of the implanter may be adjusted). Notably, the ion source 60 and the delivery line 62 are not purged between implantation steps. As described above, the particular implantation parameters selected may vary according to a number of factors. According to an exemplary embodiment in which boron is the third species to be implanted and a BF₃ source gas is included in the container 52, the implantation energy may be selected to have a value between approximately 0.1 and 20 keV to obtain a concentration in the substrate of between approximately 10¹⁴ and 10¹⁶ ions/cm² at a depth of between approximately 5 and 200 nanometers.

In a step 150 shown in FIG. 6, boron ions are implanted through a top surface 202 of the substrate 200 (as indicated by arrows 214) to a desired implantation depth and concentration to form a doped region 224 and a junction 240. According to an exemplary embodiment, the boron ions are implanted to a depth less than the depth of the first and second dopants, although according to other exemplary embodiments, the depth of the boron implant may be greater or less than that of the first and/or second implants. Advantageously, the first and second implanted species (e.g., carbon and fluorine) are intended to restrain boron diffusion during a subsequent annealing step 155.

It should be understood that the composition of the regions 222 and 224 may vary with depth (e.g., there may be a greater concentration of boron atoms at the top of region 224 than at the bottom thereof) and that there may be atoms of two or more types in a given region (e.g., region 224 may include carbon, fluorine, and boron ions implanted therein).

One advantageous feature of providing a mixture of source gases is that the ion source can run continuously throughout the co-implantation process. This saves the time required for shutting down, changing feed material and re-starting the source. In order to change species and energy, only the beamline magnets and high voltage power supplies need to be re-tuned, which is a much faster process than a complete ion source dopant change. For batch implant tools, in which multiple wafers are loaded onto a large rotating disc, it may be advantageous to leave the wafers on the disc while the beamline magnets and power supplies are re-tuned, and then to immediately begin the next co-implantation. In this manner, the time required for unloading and re-loading the wafers may be eliminated.

It should be understood that in-situ cleaning methods may also be employed, as described, for example, in U.S. Patent Provisional Application No. 60/888,311 filed Feb. 5, 2007 and International Patent Application No. PCT/US2005/038102 filed Oct. 21, 2005, the disclosures of which are incorporated herein by reference in their entirety. For example, deposits may be removed from the ion source before they are transferred in an ion beam to a substrate by using gaseous halide compounds such as XeF₂, XeF₄, XeF₆, NF₃, IF₅, IF₇, SF₆, C₂F₆, F₂, CF₄, KrF₂, Cl₂, HCl, ClF₃, ClO₂, N₂F₄, N₂F₂, N₃F, NFH₂, NH₂F, compounds of the formula CₓF_{y}, such as C₃F₆, C₃F₈, C₄F₈, and C₅F₈, compounds of the formula CₓH_{y}F_{z}, such as CHF₃, CH₂F₂, CH₃F, C₂HF₅, C₂H₂F₄, C₂H₃F₃, C₂H₄F₂, and C₂H₅F, compounds of the formula CₓH_{y}O_{z}, COF₂, HF, or organochlorides such as COCl₂, CCl₄, CHCl₃, CH₂Cl₂, and CH₃Cl, for sufficient time to at least partially remove said deposit. The conditions enabling reaction of the gaseous halide and the deposits may include any suitable conditions of temperature, pressure, flow rate, composition, etc. under which the gaseous halide chemically interacts with the material sought to be removed. Examples of various conditions that may be employed include ambient temperature, temperature in excess of ambient temperature, presence of plasma, absence of plasma, sub-atmospheric pressure, etc. Specific temperatures for such gaseous halide contacting can be in a range of from about 0° C. to about 1000° C. The contacting can involve delivery of the gaseous halide in a carrier gas, or in a neat form, or in admixture with a further cleaning agent, dopant, etc. The gaseous halide agent for chemical reaction with deposits that are at ambient temperature may be heated to increase the kinetics of the reaction.

The cleaning composition may be supplied from a source that is particularly adapted for delivery of XeF₂ or other cleaning reagent, such as the solid source delivery system more fully described in international patent application PCT/US 06/08530 for “SYSTEM FOR DELIVERY OF REAGENTS FROM SOLID SOURCES,” based on U.S. Provisional Patent Application No. 60/662,515 and U.S. Provisional Patent Application No. 60/662,396, the disclosures of which hereby are incorporated herein by reference in their respective entireties. Alternatively, the cleaning composition may be provided in the mixture of gases included in the delivery system.

While FIGS. 2-6 illustrate a method in which multiple dopants are implanted into a semiconductor substrate sequentially, according to another exemplary embodiment, each of the dopant species are implanted into the substrate simultaneously. For example, according to a particular exemplary embodiment, a source feed material utilizes a molecule that includes at least two, and preferably all, of the required species to be co-implanted into the semiconductor substrate.

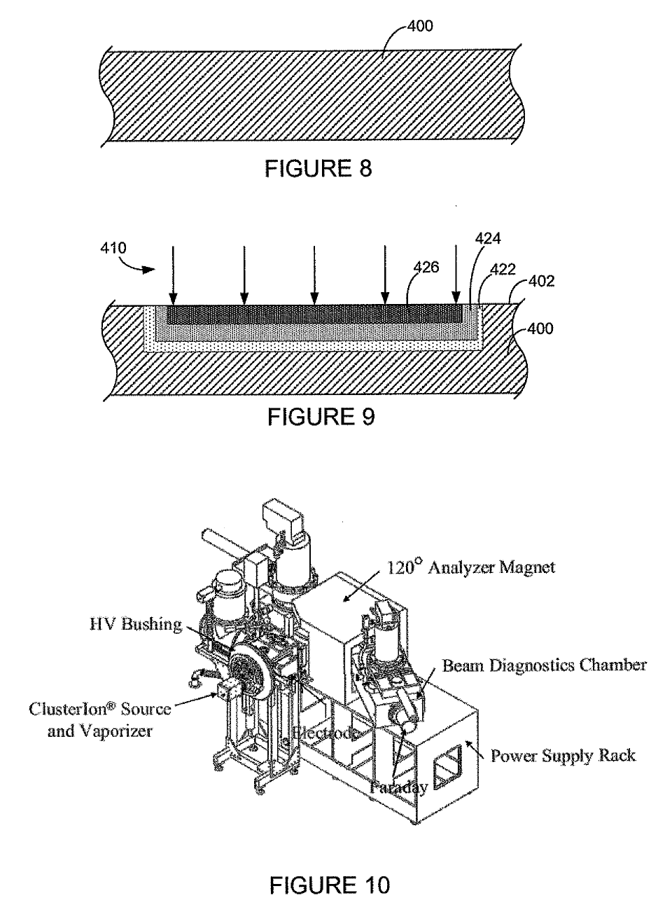

FIG. 7 is a flow diagram illustrating steps in a method 300 of forming a shallow junction in a semiconductor substrate according to an exemplary embodiment. FIGS. 8-9 are cross-sectional views of a portion of a semiconductor substrate 400 illustrating various dopant implantation steps.

According to a step 310, a semiconductor substrate or wafer 400 (illustrated, e.g., in FIG. 8) is provided into a chamber of an ion implanter. The substrate 400 may be provided in the form of a silicon wafer according to an exemplary embodiment. According to other exemplary embodiments, the substrate may comprise other suitable semiconducting materials such as silicon-germainum (Si—Ge) or gallium arsenide (GaAs). Additionally, the substrate may include other layers and/or materials, including buried oxide (BOX) layers and the like.

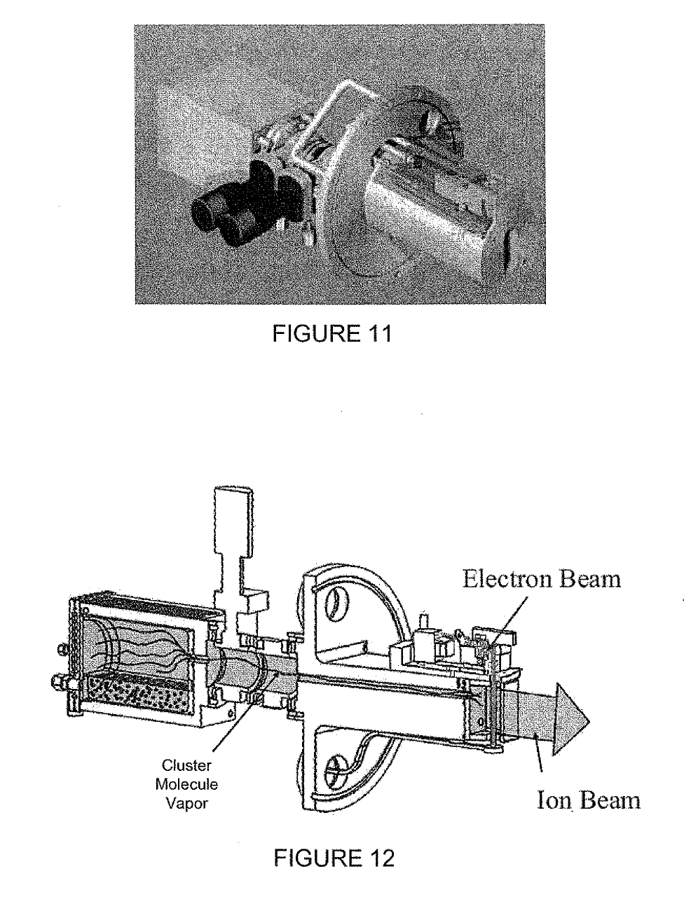

An exemplary embodiment of an ion source for delivering intact cluster molecules is illustrated in FIGS. 10-12. According to one exemplary embodiment, the ion source is a Clusterlon® ion source commercially available from SemEquip Inc. of Billerica, Mass. According to other exemplary embodiments, other types of ion sources or delivery devices may be utilized to deliver intact cluster molecules to the substrate. For example, the cluster molecules may be implanted into a substrate using plasma doping techniques and systems such as, but not necessarily limited to, those described in U.S. Patent Application Publication No. 2005/0287307.

Whereas conventional ion sources produce plasmas from source materials in which the molecules of the source materials dissociate to form ions, according to an exemplary embodiment, the ion source for delivering intact cluster molecules to a substrate uses an alternative ionization process which produces intense ion beams of large molecules without dissociation.

The various constituents of the cluster molecule are held together by electrons. Immediately upon entering the substrate (e.g., within the first several atomic layers), the binding electrons are stripped away due to the interaction with the atoms in the substrate and the constituents travel into the substrate as separate atoms (e.g., in the case of a O-carborane molecule having the general formula 1,2-C₂B₁₀H₁₂, the molecule impacts the surface of the substrate and immediately separates into 24 separate atoms, each with its own energy).

Various advantages may be obtained using a cluster ion source. For example, the implantation process utilizes much higher energy than conventional implantation processes (e.g., the total amount of energy is calculated by totaling the energy required to implant each of the individual components of the molecule into the substrate), and increases the dose rate proportionally to the number of dopant species that are included in the cluster molecule to be implanted. Additionally, beam deceleration is not required, which reduces or eliminates energy contamination and beam divergence issues associated with conventional implantation processes.

In a step 320 of the method 300, the cluster molecules are provided in a suitable container (e.g., the container 52 as shown in FIG. 1). According to one exemplary embodiment, the cluster molecule includes all of the dopant species to be implanted (e.g., the cluster molecule is a boro-fluoro-carbon molecule). According to other exemplary embodiments, the cluster molecule includes a subset of the dopant species to be implanted (e.g., where carbon, fluorine, and boron are to be implanted, the cluster molecule may be a carborane cluster molecule, with the fluorine being implanted separately either before or after the cluster molecule implantation step).

Advantageously, all of the dopant species included in the cluster molecule are implanted simultaneously into the substrate. In a step 330, the implantation parameters are selected for the cluster molecules. The implant energy of each of the atoms in the molecule is proportional to its mass and the square of its velocity. As the molecules are directed toward the surface of the substrate, the entire molecule, and each of its constituent elements, are traveling at the same velocity. Thus, the proportion of the total energy of the molecule associated with each of the individual atoms in the molecule will be proportional to the mass ratio of the atoms in the molecule. If one knows the desired implant energy for each of the constituent atoms, molecules may be selected with the appropriate mass ratios of atoms. For example, if it is desired to have an implant energy for fluorine (¹⁹F) atoms of approximately 1.9 keV and for boron (¹¹B) atoms of approximately 1.1 keV, a molecule such as BF₃ may be utilized at a total implant energy of 6.8 keV.

In a step 340 shown in FIG. 9, cluster molecules are implanted through a top surface 402 of the substrate 400 (as indicated by arrows 410) such that the constituents of the molecule are implanted to a desired implantation depth and concentration. As illustrated in FIG. 9, three separate regions 422, 424, and 426 are formed in the substrate, each having a different composition. For example, according to an exemplary embodiment, region 422 may represent a region in which fluorine ions have been implanted, region 424 may represent a region in which carbon ions have been implanted, and region 426 may represent a region in which boron ions have been implanted (i.e., the ultra-shallow junction region). According to an exemplary embodiment, each of the regions 422, 424, and 426 are formed simultaneously. According to another exemplary embodiment, one of the regions is formed before the other two (e.g., region 422 is doped with fluorine ions, after which regions 424 and 426 are formed simultaneously by implanting a cluster molecule including both carbon and boron atoms). Advantageously, certain of the implanted dopant species (e.g., fluorine and carbon) may act to restrain boron diffusion during a subsequent annealing step 350.

It should be understood that the composition of the regions 422, 424, and 426 may vary with depth (e.g., there may be a greater concentration of boron atoms at the top of region 426 than at the bottom thereof) and that there may be atoms of two or more types in a given region (e.g., region 426 may include carbon, fluorine, and boron ions implanted therein).

According to one exemplary embodiment, only one type of cluster molecule is implanted into a substrate. According to other exemplary embodiments, more than one type of cluster molecule may be implanted into the same substrate to provide a desired dopant profile in the substrate. Additionally, whether one or more than one type of cluster molecule are implanted into a substrate, other dopant species may also be implanted in separate steps to add different dopant species to the substrate and/or to supplement the dopants provided by the cluster molecules (e.g., CH₃ gas may be used as a source to provide carbon doping for the substrate and/or to supplement the carbon doping provided by the cluster molecules).

The particular type of cluster molecules used may be selected based on any of a variety of factors, including commercial availability, cost, ease of use, molecular composition, and other relevant factors. Cluster molecules may be in gaseous form (e.g., BF₂CH₃; 1,5-C₂B₃H₅ and derivatives thereof that include functional groups having between 1 and 4 carbon atoms (e.g., —CH₃) in place of one or more of the hydrogen atoms); liquid form (e.g., o-carborane (1,2-C₂B₁₀H₁₂) derivatives that are liquid at room temperature, such as those including one or more of the following functional groups: 1-C₂H₅, 1-CH(CH₃)₂, and —B-nC₃H₇); or in solid form (e.g., carborane molecules such as o-carborane 1,2-C₂B₁₀H₁₂) according to various exemplary embodiments. According to still other exemplary embodiments, the cluster molecules may be 1,7-C₂B₆H₈ (either alone or with a 1,7-(CH₃)₂ functional group); 1,7-C₂B₇H₉ (either alone or with a 1,7-(CH₃)₂ functional group); or 1,6-C₂B₈H₁₀ (either alone or with a 1,6-(CH₃)₂ functional group). In another exemplary embodiment, the cluster molecules may be CB₅H₉, C₂B₄H₈, C₃B₃H₇, C₄B₂H₆, C₂B₃H₇, C₂B₇H₁₃, C₂B₃H₅, C₂B₄H₆, C₂B₅H₇, CB₅H₇, C₂B₆H₈, C₂B₇H₉, C₂B₈H₁₀, C₂B₉H₁₁, C₂B₁₀H₁₂ or derivatives of these molecules.

According to an exemplary embodiment, the cluster molecules may be provided as boronic acids or as simple organo boron molecules such as trimethyl borates (TMB) (one example of which has the general formula B—(O—CH₃)₃). Such molecules typically include one boron atom per molecule, and include C—B and C—O—B bonded species. Some molecules are readily available and relatively inexpensive, although in certain applications, such molecules may not provide adequate boron content to achieve the desired characteristics for an ultra-shallow junction. Examples of such molecules include BF₂CH₃, CBO₂H₅, and C₂BO₂H₈.

According to still other exemplary embodiments, boron hydride clusters may be used such as those having a formula BA where 5≦x≦96 and y≦x+8 as described, for example, in U.S. patent application Ser. No. 11/041,558 (Publication No. 2005/0163693), the disclosure of which is incorporated herein by reference (e.g., B₁₈H₂₂).

According to an exemplary embodiment in which a trimethyl borate type cluster molecule is to be implanted into a silicon substrate, the implantation energy of the cluster molecule may be selected to have a value between approximately 1 and 100 keV. This cluster implant would result in an equivalent carbon implant energy of between approximately 0.115 keV and 11.5 keV, and an equivalent boron implant energy of between approximately 0.106 keV and 10.6 keV, wherein the implanted dose of carbon atoms would be 3 times greater than the implanted dose of boron atoms.

According to another exemplary embodiment, the cluster molecules may be provided in the form of carboranes having the general formula C_{X}B_{y}H_{z}. Such molecules are relatively stable and readily available, and include relatively low carbon content in each molecule. Examples of such molecules include o-carboranes and its derivatives, which are commercially available from Sigma-Aldrich of St. Louis, Mo. and from Strem Chemicals, Inc. of Newburyport, Mass. Other examples include p and m-carboranes and their derivatives, which are commercially available from Katchem S.R.O. of the Czech Republic.

According to an exemplary embodiment in which a cluster molecule having the general formula 1,2-C₂B₁₀H₁₂ is to be implanted into a silicon substrate, the implantation energy may be selected to have a value between approximately 1 and 100 keV to obtain an effective carbon energy in the substrate of between approximately 0.082 and 8.2 keV and an effective boron energy in the substrate of between approximately 0.075 and 7.5 keV, wherein the implanted dose of boron atoms would be 5 times greater than the implanted dose of carbon atoms. The hydrogen included in the molecule diffuses out upon implantation into the substrate.

According to other exemplary embodiments, the cluster molecules may be provided in the form of carborane derivatives, which are generally characterized as having lower melting points than conventional carboranes. Such molecules include a main carborane structure similar to that described above (e.g., o-carborane 1,2-C₂B₁₀H₁₂) and also one or more substituted groups attached in place of hydrogen atoms (e.g., the derivative may be a fluorinated derivative in which CF₃ may be substituted for one or more of the hydrogen atoms so that carbon, boron, and fluorine atoms are each present in the cluster molecule). Other potential substituted groups include fluorides (—Fₓ) and C₆H₄F (e.g., C₂B₁₀H₁₂F₁₀ or fluorinated derivatives of m- or p-carboranes). According to a particular exemplary embodiment, a carborane derivative having the general formula o-carborane, 1-m-C₆H₄F with a melting point of approximately 68 degrees Celsius may be used. As those reviewing the present disclosure will readily appreciate, a relatively large number of combinations are possible according to various exemplary embodiments, all of which are intended to be within the scope of the present disclosure.

According to other exemplary embodiments, cluster molecules may be provided in the form of small carboranes (e.g., 1,5-C₂B₃H₅; 1,2-C₂B₄H₆; 1,2-C₂B₅H₇; and 1,2-C₂B₈H₁₀). According to an exemplary embodiment in which a cluster molecule having the general formula 1,5-C₂B₃H₅ is to be implanted into a silicon substrate, the implantation energy may be selected to have a value between approximately 1 and 100 keV to obtain an effective carbon energy in the substrate of between approximately 0.19 and 19 keV and an effective boron energy in the substrate of between approximately 0.18 and 18 keV, wherein the implanted dose of boron atoms would be 1.5 times greater than the implanted dose of carbon atoms.

Those reviewing this disclosure will appreciate that one advantage of utilizing cluster molecules is that some or all of the co-implants are achieved in a single implant. By eliminating implant steps, productivity and efficiency may be improved as compared to sequential doping methods.

In addition, the effective implant energy of each species is reduced by the ratio of the species atomic weight to the cluster's molecular weight. This means that very low effective implant energies, which are important in forming shallow junctions, may be achieved at higher extraction energy for the molecule. The higher extraction energy is beneficial for obtaining higher extracted beam current, thereby further improving productivity.

Those reviewing this disclosure will appreciate that the methods described according to the various exemplary embodiments provide various advantages over conventional implantation methods. For example, the methods described herein provide more efficient and less labor-intensive implantation of multiple implantation species, since the ion source need not be shut down, evacuated, and re-started between implantation steps. The implantation of the various dopant species described herein may provide effective ways to reduce or eliminate undesirable boron diffusion in a substrate into which it is implanted (and the methods and species described herein may also find utility in reducing or eliminating undesirable of other implanted dopant species such as phosphorous).

Where a range of values are provided herein in descriptions of chemical moiety, it is to be understood that intervening numbers and any other stated or intervening values in that stated range are encompassed therein. For example, where a range of carbon numbers is provided herein in a description of a corresponding chemical moiety, it is understood that each intervening carbon number and any other stated or intervening carbon number value in that stated range, is encompassed within the scope of the disclosure, e.g., C1-C6 alkyl is understood as including methyl (C1), ethyl (C2), propyl (C3), butyl (C4), pentyl (C5) and hexyl (C6), and the chemical moiety may be of any conformation, e.g., straight-chain or branched, it being further understood that sub-ranges of carbon numbers within specified carbon number ranges may independently be included in smaller carbon number ranges, within the scope of the invention, and that ranges of carbon numbers specifically excluding a carbon number or numbers are included in the invention, and sub-ranges excluding either or both of carbon number limits of specified ranges are also included in the invention.

It is also important to note that the various exemplary embodiments described herein are intended to be illustrative only. Although only a few embodiments have been described in detail in this disclosure, those skilled in the art who review this disclosure will readily appreciate that many modifications are possible without materially departing from the novel teachings and advantages of the subject matter recited in the claims. The order or sequence of any process or method steps may be varied or re-sequenced according to other exemplary embodiments. Other substitutions, modifications, changes and omissions may be made in the design, operating conditions and arrangement of the various exemplary embodiments without departing from the scope of the present inventions as expressed in the appended claims.

What is claimed is:

1. A method for producing a doped region in a semiconductor substrate comprising performing a first implant step in which a carborane cluster molecule is implanted into a semiconductor substrate to form a doped region.

2. The method of claim 1, wherein the carborane cluster molecule is a o-carborane molecule having the general formula 1,2-C₂B₁₀H₁₂; or the carborane cluster molecule is selected from a group consisting of 1,5-C₂B₃H₅, 1,2-C₂B₄H₆, 1,2-C₂B₅H₇ and 1,2-C₂B₈H₁₀; or the carborane cluster molecule is a o-carborane derivative; or the o-carborane derivative comprises a fluorinated carborane derivative; or the carborane cluster molecule is selected from a group consisting of CB₅H₉, C₂B₄H₈, C₃B₃H₇, C₄B₂H₆, C₂B₃H₇, C₂B₇H₁₃, C₂B₃H₅, C₂B₄H₆, C₂B₅H₇, CB₅H₇, C₂B₆H₈, C₂B₇H₉, C₂B₈H₁₀, C₂B₉H₁₁, and C₂B₁₀H₁₂ or derivatives thereof.

3. The method of claim 1, further comprising performing a second implant step in which a dopant species is implanted into the semiconductor substrate.

4. The method of claim 3, wherein the dopant species is not boron or carbon.

5. The method of claim 3, wherein the dopant species comprises carbon.

6. The method of claim 3, wherein the dopant species comprises boron.

7. The method of claim 3, wherein the second implant step comprises implanting a cluster molecule into the substrate that is different from the carborane cluster molecule implanted in the first implant step.

8. The method of claim 1, further comprising annealing to activate at least one of the first dopant and the second dopant.

9. An apparatus for forming doped regions in a semiconductor substrate comprising a stage for holding a semiconductor substrate and means for implanting a carborane cluster molecule into the semiconductor substrate to form a doped region, wherein the carborane cluster molecule is a o-carborane molecule having the general formula 1,2-C₂B₁₀H₁₂; or the carborane cluster molecule is selected from a group consisting of 1,5-C₂B₃H₅, 1,2-C₂B₄H₆, 1,2-C₂B₅H₇ and 1,2-C₂B₈H₁₀; or the carborane cluster molecule is a o-carborane derivative.

10. A method for producing a semiconductor device having a shallow junction region, the method comprising:
providing a first gas and a second gas in a container, the first gas comprising a first dopant and the second gas comprising a second dopant;
implanting the first dopant into a semiconductor substrate using an ion source; and
implanting the second dopant into the semiconductor substrate using the ion source;
wherein the ion source is not turned off between the steps of implanting the first dopant and implanting the second dopant.

11. The method of claim 10, wherein at least one of the first gas and the second gas is CH₃; or at least one of the first gas and the second gas is BF₃.

12. The method of claim 10, further comprising implanting a third dopant into the semiconductor substrate after implanting the second dopant using the ion source, wherein the ion source is not turned off between the step of implanting the second dopant and implanting the third dopant.

13. The method of claim 12, wherein the third dopant is included in at least one of the first gas and the second gas.

14. The method of claim 12, wherein the first dopant is carbon, the second dopant is fluorine, and the third dopant is boron.

15. The method of claim 12, wherein the third dopant is implanted to a lesser depth than at least one of the first dopant and the second dopant.

16. The method of claim 10, further comprising providing a third gas in the container with the first gas and the second gas.

17. The method of claim 16, wherein the first gas is a carbon source gas, the second gas is a fluorine source gas, and the third gas is a boron source gas.

18. The method of claim 16, wherein at least one of the first gas, the second gas, and the third gas acts as a source for a dopant species selected from the group consisting of phosphorous, arsenic, indium, and antimony.

19. The method of claim 10, wherein the first dopant is carbon and the second dopant is boron.

20. The method of claim 10, wherein the first dopant is fluorine and the second dopant is boron.

21. The method of claim 10, wherein one of the first dopant and the second dopant is fluorine and other of the first dopant and the second dopant is boron.

22. The method of claim 10, further comprising annealing to activate at least one of the first dopant and the second dopant to form a shallow junction, wherein at least one of the first dopant and the second dopant act to restrain boron diffusion.
